(19) United States
(12) Patent Application Publication
(10) Pub. No.: US 2026/0101752 A1
(43) Pub. Date: Apr. 9, 2026

(54) HEAT DISSIPATION THROUGH REDISTRIBUTION STRUCTURE

(71) Applicant: Taiwan Semiconductor Manufacturing Company, Ltd., Hsinchu (TW)

(72) Inventors: Hsin-Yu Chen, Taipei City (TW); Meng-Wei Chou, Hsinchu County (TW); Jyun-Siang Peng, Hsinchu City (TW); Yu-Hsiang Hu, Hsinchu City (TW); Chien-Hsun Lee, Hsin-chu County (TW); Kathy Wei Yan, Hsinchu (TW)

(21) Appl. No.: 19/037,097

(22) Filed: Jan. 25, 2025

Related U.S. Application Data
(60) Provisional application No. 63/703,737, filed on Oct. 4, 2024.

(51) Int. Cl. H01L 23/58; H01L 21/48; H01L 23/00; H01L 23/367; H01L 23/373; H01L 23/538; H01L 25/16; H05K 1/18; H10B 80/00; H10D 80/20; H10D 80/30

(52) U.S. Cl. CPC H10W 42/00; H10D 80/20; H10W 40/228; H10W 40/258; H10W 70/611; H10W 70/65; H10W 90/401; H05K 1/181; H10B 80/00; H10D 80/30; H10W 70/02; H10W 90/00; H10W 90/724

(57) ABSTRACT

A semiconductor package structure according to the present disclosure includes a substrate, an interposer bonded to the substrate by way of a plurality of first type solder features, and an integrated circuit (IC) die bonded to the interposer by way of a plurality of second type solder features. The interposer includes a redistribution structure and a seal ring structure extending around the redistribution structure. At least one of the plurality of second type solder features is electrically coupled to the seal ring structure.

### PRIORITY DATA

This application claims the benefit of U.S. Provisional Application No. 63/703,737, filed Oct. 4, 2024, which is hereby incorporated by reference in its entirety.

### BACKGROUND

In some Three-Dimensional Integrated Circuits (3DIC), device dies are bonded to a package substrate to form a package. The heat generated by the device dies during operation needs to be dissipated to prevent performance degradation or even physical damage.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic top view of a package structure that includes a first thermal dissipation structure, according to various aspects of the present disclosure.

FIG. 2 illustrates a fragmentary cross-sectional view of the package structure in FIG. 1, according to various aspects of the present disclosure.

FIG. 3 illustrates a schematic top view of a package structure that includes a second thermal dissipation structure, according to various aspects of the present disclosure.

FIG. 4 illustrates a fragmentary cross-sectional view of the package structure in FIG. 3, according to various aspects of the present disclosure.

FIG. 5 illustrates a schematic top view of a package structure that includes a third thermal dissipation structure, according to various aspects of the present disclosure.

FIG. 6 illustrates a fragmentary cross-sectional view of the package structure in FIG. 5, according to various aspects of the present disclosure.

FIG. 7 illustrates a schematic cross-sectional view of a first thermal bump feature and a first thermal contact via, according to various aspects of the present disclosure.

FIG. 8 illustrates a schematic cross-sectional view of a second thermal bump feature and more than one second thermal contact via, according to various aspects of the present disclosure.

FIG. 9 illustrates a schematic cross-sectional view of a third thermal bump feature and a third thermal contact via, according to various aspects of the present disclosure.

FIG. 10 illustrates a flowchart of a method for implementing thermal dissipation structures in a package structure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Throughout the present disclosure, unless expressly otherwise described, like reference numerals denote like features.

Semiconductor packaging technologies were once just considered backend processes that facilitates chips to interface external circuitry. Times have changed. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. To dissipate heat from a 3D package, a heat sink may be placed on top of the top dies to direct heat upward and away from the top dies.

The present disclosure provides a thermal dissipation structure that directs heat away from hot spots in an IC die and into an interposer or a package substrate on which the IC die mounts. The thermal dissipation structure includes thermal micro bumps adjacent a hot spot. While these thermal micro bumps are not electrically coupled to any transistors in the IC die, they are electrically coupled to a seal ring around an edge of an interposer on which the IC die bonds. The seal ring is electrically coupled to at least one solder bump to interface a package substrate on which the interposer bonds. The at least one solder bump may be coupled to a conductive feature in the package substrate. The thermal dissipation structure does not serve any circuit functions or power distribution. Its metal construction helps dissipate heat into the seal ring in the interposer or conductive features in the package substrate.

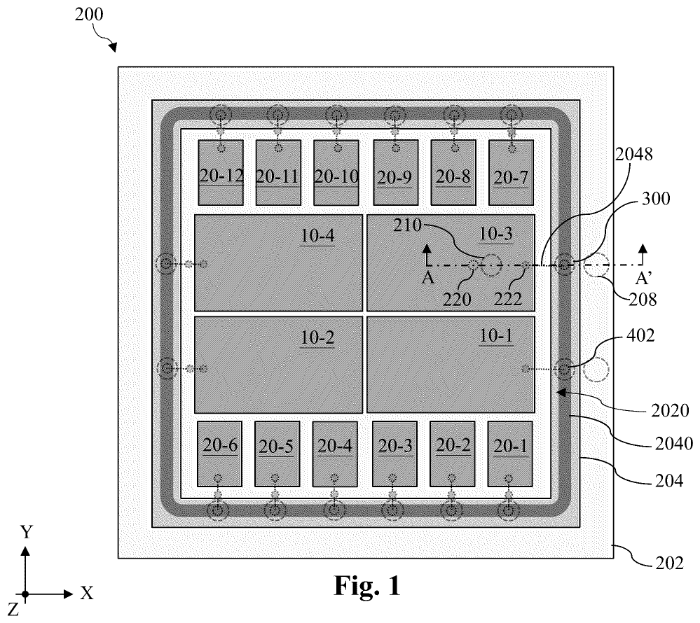

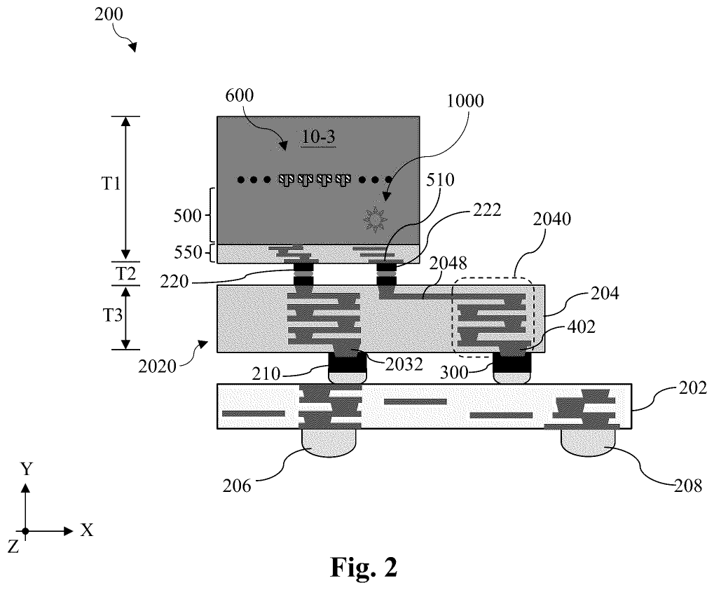

FIG. 1 illustrates a top view of a package structure 200 that includes a first thermal dissipation structure. FIG. 2 illustrates a fragmentary cross-sectional view along line A-A′ in FIG. 1. In the depicted embodiment, the package structure 200 includes a package substrate 202, an interposer 204 disposed over and bonded to the package substrate 202, and a plurality of dies disposed over and bonded to the interposer 204. In some embodiments, the package substrate 202 may include a printed circuit board (PCB) or the like. For example, the package substrate 202 may include conductive traces disposed in insulation layers. The conductive traces may be formed of copper and the insulation layers may include fiberglass reinforced epoxy (e.g., FR-4) or Ajinomoto Built-up Film (ABF). While not explicitly shown in the figures, the package substrate 202 may include through-substrate vias (TSVs) or through hole connectors that extend from a frontside surface of the package substrate 202 to a backside surface of the package substrate 202. In order to electrically couple to the interposer 204, the package substrate 202 may include a plurality of contact pads over the frontside surface. For connections to solder bumps, such as solder bumps 206 and 208 shown in FIG. 2, the package substrate 202 may include contact pads on the backside surface. While not shown in the figures, passive components, such as capacitors, resistors, or inductors, may be bonded on the package substrate 202.

The interposer 204 may be a silicon interposer or an organic interposer. As used herein, a silicon interposer includes a silicon substrate and through-silicon vias extending through the silicon substrate. An organic interposer includes a plurality of redistribution layers embedded in a plurality of insulation layers. Because the redistribution layers allow the organic interposer to better signal redistribution functions, organic interposers have gained more popularity when the interposer is required to perform more than signal pass-through functions. In the depicted embodiments, the interposer 204 is an organic interposer that includes a plurality of redistribution layers. Each of the redistribution layers is formed by depositing a seed layer over a patterned insulation layer, patterning the seed layer, and depositing a metal layer over the seed layer using electroplating or electroless plating techniques. In some instances, the seed layer may include an adhesion layer and a copper-containing layer. The adhesion layer may include titanium, titanium nitride, tantalum, or tantalum nitride. The copper-containing layer may include copper or an alloy thereof. The metal layer may include copper, aluminum, nickel, cobalt, or palladium. The insulating layers in the interposer 204 may include polybenzoxazole (PBO), polyimide, benzocyclobutene (BCB), or alike. In some implementations, the interposer 204 may include between 3 and 15 redistribution layers.

In some embodiments, the interposer 204 includes a seal ring structure 2040 extending continuously along an edge of the interposer 204. A seal ring structure, such as the seal ring structure 2040, is intended to prevent or reduce water ingress into functional redistribution features surrounded by the seal ring structure. Theoretically, an organic interposer like the interposer 204 is less prone to water ingress and the seal ring structure 2040 is not necessary. In the depicted embodiments, the interposer 204 includes the seal ring structure 2040 as a heat sink of the thermal dissipation structure. For ease of reference based on their functions, the interposer 204 may be said to include a redistribution structure 2020 and the seal ring structure 2040. As shown in FIGS. 1 and 2, the seal ring structure 2040 continuously extends around the redistribution structure 2020. Referring to FIG. 2, the seal ring structures 2040 includes interconnected redistribution lines and vias that vertically extend through the entire Z-direction thickness of the interposer 204. This continuous, wall-like structure is a legacy of a seal ring wall that is intended to prevent water ingress. In some embodiments represented in FIG. 2, the interposer 204 is bonded to the frontside surface of the package substrate 202 by way of bump features such as a functional bump feature 210 and a thermal bump feature 300. The bump features may include ball grid array (BGA) connectors, solder balls, metal pillars, controlled collapse chip connection (C4) bumps, micro bumps, electroless nickel-electroless palladium-immersion gold technique (ENEPIG) formed bumps, or the like. In the depicted embodiment, the bump features are C4 bumps, which may include lead, tin, silver, or alloy thereof. The functional bump feature 210 is coupled to the redistribution structure 2020 by way of a contact via 2032. The thermal bump feature 300 is coupled to the seal ring structure 2040 by way of a thermal contact via 402. Within the interposer, the seal ring structure 2040 is electrically insulated from the redistribution structure 2020. As shown in FIG. 2, the functional bump feature 210 is electrically coupled to the solder bump 206 by way of conductive traces in the package substrate 202. In some embodiments represented in FIG. 2, the thermal bump feature 300 is not electrically coupled to any conductive traces in the package substrate 202. This means that the seal ring structure 2040 and the thermal bump feature 300 are the terminal heat sink.

Reference is now made to FIG. 1. The package structure 200 includes a plurality of dies bonded to the interposer 204. In some implementations, the plurality dies may include a plurality of central dies and a plurality of peripheral dies. The central dies include system dies, such as System-on-Chip (SoC) dies or System-on-Integrated Chips (SoIC) dies and the peripheral dies include memory dies, electronic dies, or photonic dies. In the depicted embodiments shown in FIG. 1, the peripheral dies include a first memory die 20-1, a second memory die 20-2, a third memory die 20-3, a fourth memory die 20-4, a fifth memory die 20-5, a sixth memory die 20-6, a seventh memory die 20-7, an eighth memory die 20-8, a nineth memory die 20-9, a tenth memory die 20-10, an eleventh memory die 20-11, and a twelfth memory die 20-12 and the central dies include a first system die 10-1, a second system die 10-2, a third system die 10-3, and a fourth system die 10-4. Each of the system dies may include a graphic processing unit (GPU), a central processing unit (CPU), a neural processing unit (NPU), or a combination thereof to perform various applications. Each of the memory dies may include a high-bandwidth-memory (HBM) construction. HBM is a computer memory interface that is commonly used in conjunction with high-performance graphics accelerators, high-performance data center, application specific integrated circuit (ASIC) for AI application, on-package cache in CPUs, or high-performance computing ICs. In the depicted embodiments, each of the memory die include a dynamic random access memory (DRAM) stack die (or memory stack die) and a controller die that is bonded to the DRAM stack die. In some instances, the DRAM stack die may include 2 to 10 DRAM dies stacked vertically.

Each of the plurality of dies includes transistors fabricated on a substrate and an interconnect structure. In some implementations, each of the plurality of dies may further includes a redistribution layer. To better illustrate, a fragmentary cross-sectional view along line A-A′ in FIG. 2 is shown in FIG. 2. Line A-A′ cuts through a portion of the third system die 10-3, the interposer 204, and the package substrate 202. As representatively shown in FIG. 2, the third system die 10-3 includes a plurality of transistors 600 fabricated on a substrate, such as a silicon substrate. In some instances, the transistors 600 may include multi-gate transistors where a gate structure engages more than two surfaces of a channel feature. For example, the transistors 600 may include fin-type field effect transistors (FinFETs) or gate-all-around (GAA) transistors. The transistors 600 are interconnected by an interconnect structure 500. The interconnect structure 500 includes between about 9 and about 20 interconnect layers. Each of the interconnect layers includes metal lines disposed in an intermetal dielectric (IMD) layer. Metal lines in different interconnect layers are connected by metal vias. In the depicted embodiments, a redistribution layer 550 is disposed over the interconnect structure 500. Dies in the package structure 200 are bonded to the interposer 204 by way of functional micro bumps and thermal micro bumps. In FIG. 2, the third system die 10-3 is bounded to the interposer 204 by way of a functional micro bump 220 and a thermal micro bump 222. As used herein, functional micro bumps, are electrically connected to one or more transistors in the overlying die and the thermal micro bumps are insulated from all of the transistors in the overlying die. Referring to FIG. 2, the functional micro bump 220 is electrically coupled to at least one of the transistors 600 by way of the redistribution layer 550 and the interconnect structure 500. The thermal micro bump 222 does not serve as any circuit function and is electrically insulated from all of the transistors 600. In FIG. 2, the thermal micro bump 222 is electrically and physically coupled to a redistribution line 510 that is farther away from the transistors 600. Because the redistribution line 510 is not electrically coupled to any other redistribution lines or conductive features in the redistribution layer 550, the thermal micro bump 222 is insulated from the rest of the redistribution layer 550, all metal lines in the interconnect structure 500, and all of the transistors 600. In the depicted embodiments, the thermal micro bump 222 is electrically coupled to the seal ring structure 2040 by way of a redistribution line 2048 in the interposer 204. The redistribution line 2048 helps direct heat in the seal ring structure 2040.

Reference is now made to FIGS. 1 and 2. As will be discussed further below, the thermal micro bump 222 is inserted to be placed in vicinity of a hot spot 1000 in the third system die 10-3. The thermal micro bump 222 help conduct heat away from the hot spot 1000 to lower a temperature at the hot spot 1000. In embodiments representatively shown in FIG. 1, each of the dies (including the first memory die 20-1, the second memory die 20-2, the third memory die 20-3, the fourth memory die 20-4, the fifth memory die 20-5, the sixth memory die 20-6, the seventh memory die 20-7, the eighth memory die 20-8, the nineth memory die 20-9, the tenth memory die 20-10, the eleventh memory die 20-11, the twelfth memory die 20-12, the first system die 10-1, the second system die 10-2, the third system die 10-3, and the fourth system die 10-4) may include a hot spot. For that reason, FIG. 1 illustrates that each of the dies may dissipate heat to the seal ring structure 2040 by way of a thermal micro bump. In other embodiments, thermal micro bumps and the connections to the seal ring structure 2040 are only implemented to dissipate heat from some of the dies.

It should be noted that thermal micro bumps, such as the thermal micro bump 222, are different from dummy micro bumps. A thermal micro bump according to the present disclosure is electrically connected to at least one redistribution line in the redistribution layer 550 and at least one redistribution line in the interposer 204. This connection ensures a continuity of metal structures that help conduct heat away from a hot spot.

Reference is still made to FIG. 2. In some implementations, each of the die, such as the third system die 10-3, has a first thickness T1. The thermal micro bump 222 or the functional micro bump 220 may have a second thickness T2. The interposer 204 may include a third thickness T3. In some instances, the first thickness T1 may be between about 620 μm and about 700 μm, the second thickness T2 may be between about 30 μm and about 40 μm, and the third thickness T3 may be between about 50 μm and about 100 μm. While not explicitly shown in FIG. 2, an underfill is deposited between the package substrate 202 and the interposer 204 to surround the functional micro bump 220 and the thermal micro bump 222. Similarly, an underfill is deposited between the dies and the interposer 204 to surround the functional micro bump 220 and the thermal micro bump 222.

For ease of reference, the thermal micro bump 222, the redistribution line 2048 in the redistribution layer 550, the seal ring structure 2040 in the interposer 204, and the thermal bump feature 300 may be collectively referred to as a first thermal dissipation structure.

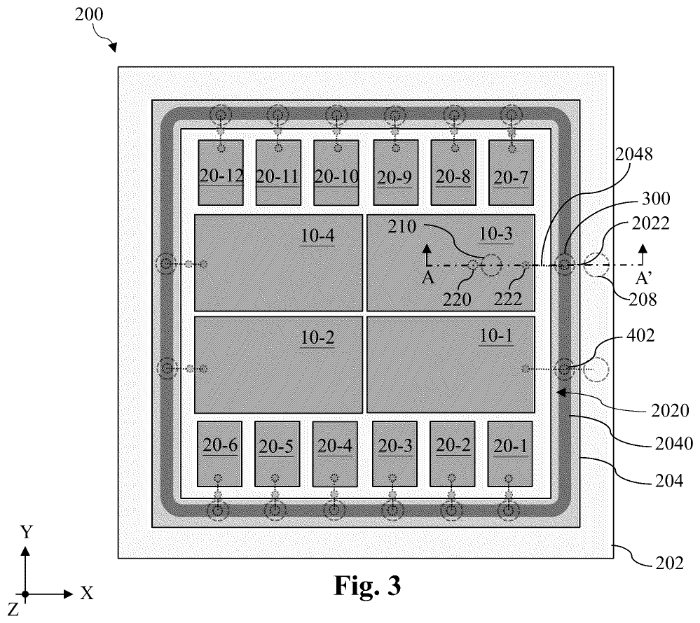

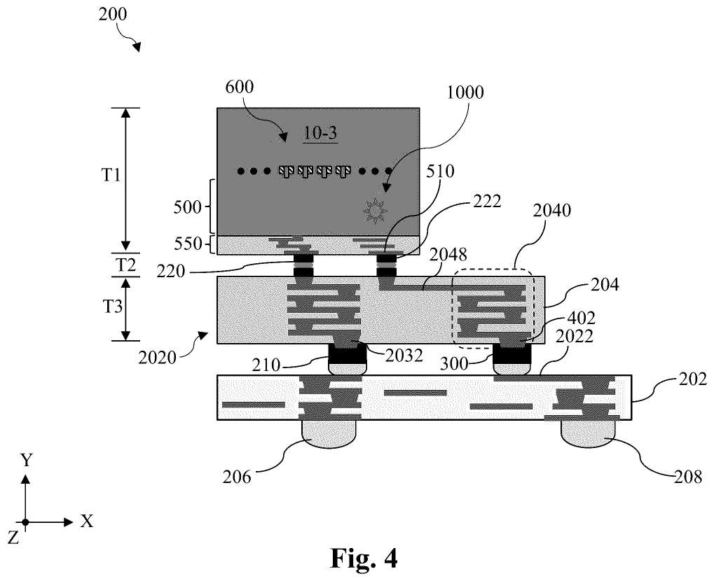

FIG. 3 illustrates a top view of a package structure 200 that includes a second thermal dissipation structure. FIG. 4 illustrates a fragmentary cross-sectional view along line A-A′ in FIG. 3. The second thermal dissipation structure illustrated in FIGS. 3 and 4 is different from the first thermal dissipation structure in that the second thermal dissipation structure further extends into the package substrate 202. In FIG. 2, the thermal bump feature 300 lands on an insulation layer in the package substrate 202 and is insulated from all conductive traces in the package substrate 202. Contrarily, the thermal bump feature 300 bonds to a thermal conductive trace 2022, which may be electrically connected to other conductive traces in the package substrate 202. In some embodiments represented in FIG. 4, the thermal conductive trace 2022 may be further coupled to the solder bump 208. In these embodiments, when the package substrate 202 is mounted to a further substrate by way of the solder bumps, the solder bump 208 is not bonded to any function circuit. This means that the solder bump 208 in the second thermal dissipation structure is a thermal solder bump and serves as a part of the heat sink. The second thermal dissipation structure shown in FIGS. 3 and 4 includes the thermal micro bump 222, the redistribution line 2048 in the interposer 204, the seal ring structure 2040 in the interposer 204, the thermal bump feature 300, the thermal conductive trace 2022, the solder bump 208, and other conductive traces that are electrically coupled to the thermal conductive trace 2022.

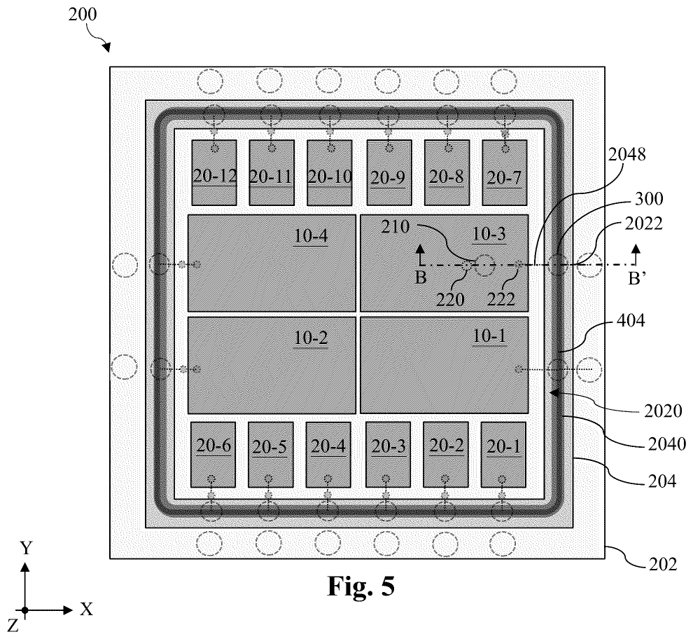

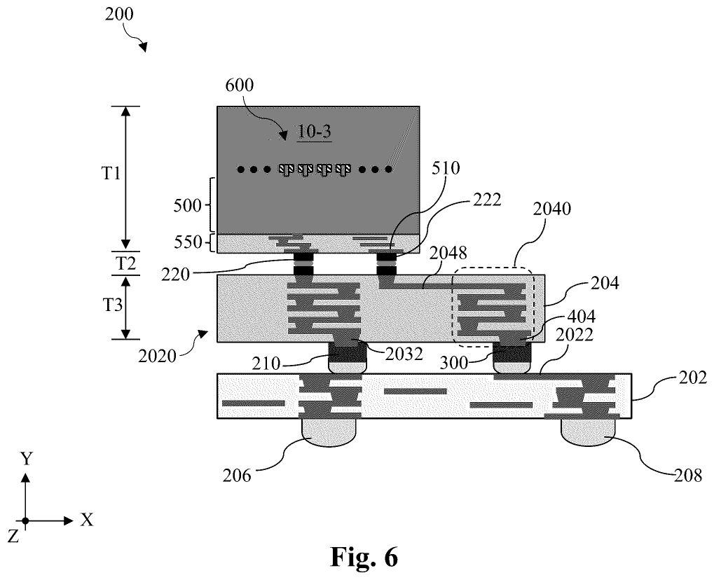

FIG. 5 illustrates a top view of a package structure 200 that includes a third thermal dissipation structure. FIG. 6 illustrates a fragmentary cross-sectional view along line A-A′ in FIG. 5. The third thermal dissipation structure illustrated in FIGS. 5 and 6 is different from the second thermal dissipation structure in that the seal ring structure 2040 is electrically coupled to the thermal bump feature 300 by way of a thermal via ring 404. While a cross-sectional view of the thermal via ring 404 is similar to the cross-sectional view of the thermal contact via 402, a top view of the thermal via ring 404 shows that the thermal via ring 404 extends continuously around the redistribution structure 2020. The thermal via ring 404 may be regarded as an extension of the seal ring structure 2040. Because the thermal via ring 404 extends along an edge of the interposer 204, the thermal via ring 404 interfaces more than one thermal bump features. The same cannot be said to the thermal contact via 402, which interfaces only the thermal bump feature 300.

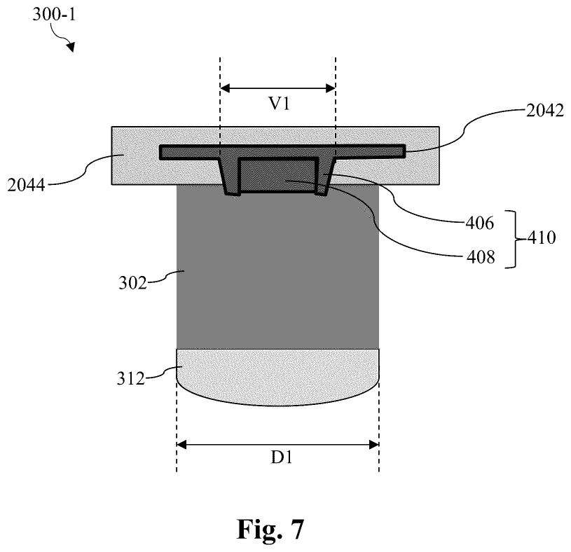

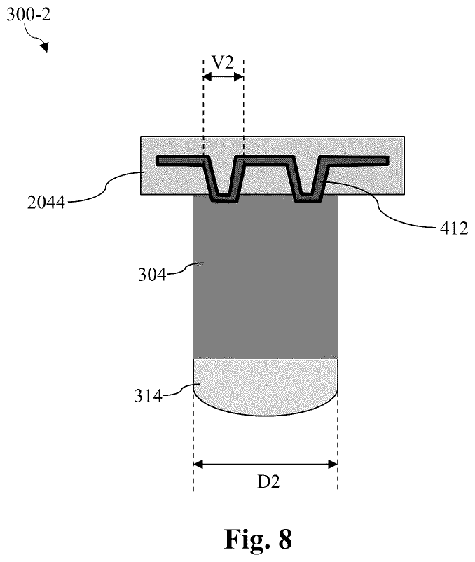

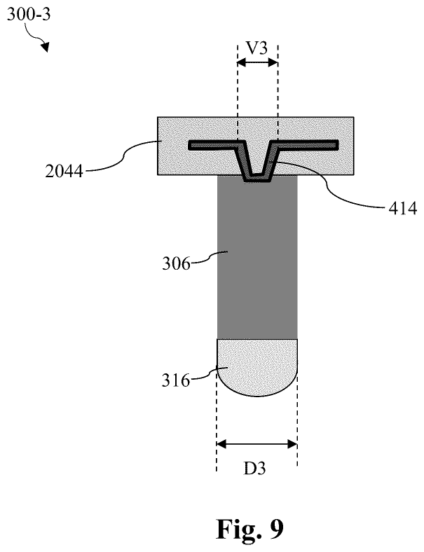

The thermal bump feature 300 may come in different sizes and configurations to be deployed in different environments. FIG. 7 illustrates a first thermal bump feature 300-1 and a first thermal contact via 410. FIG. 8 illustrates a second thermal bump feature 300-2 and a second thermal contact via 412. FIG. 9 illustrate a third thermal bump feature 300-3 and a third thermal contact via 414. Out of the three, the first thermal bump feature 300-1 has the largest footprint and the third thermal bump feature 300-3 has the smallest footprint. The second thermal bump feature 300-2 has a footprint that of the first thermal bump feature 300-1 and that of the third thermal bump feature 300-3. The first thermal contact via 410 has a multi-layer construction to have a greater dimension to correspond to mechanically support the first thermal bump feature 300-1. The second thermal bump feature 300-2 is coupled to the seal ring structure 2040 by way of more than one second thermal contact via 412. Each of the second thermal contact via 412 is smaller than the first thermal contact via 410. The third thermal bump feature 300-3 is coupled to the seal ring structure 2040 by way a single third thermal contact via 414. In some embodiments, the dimension and construction of the first thermal bump feature 300-1 are substantially similar to those of the functional bump feature 210 shown in FIGS. 2, 4 and 6. The smaller dimensions of the second thermal bump feature 300-2 and the third bump feature 300-3 allow them to be inserted in designs that are already crowded with functional bump features similar to the functional bump feature 210.

FIG. 7 illustrates a schematic cross-sectional view of a first thermal bump feature 300-1. The first thermal bump feature 300-1 includes a first copper pillar 302 and a first solder cap 312 over the first copper pillar 302. In some embodiments, the first copper pillar 302 may include copper (Cu), nickel (Ni), or cobalt (Co) and the first solder cap 312 may include tin (Sn), silver (Ag). In some embodiments, the first thermal bump feature 300-1 is substantially circular in a top view and has a first diameter D1. In some instances, the first diameter D1 may be between about 40 μm and about 100 μm. In order to reduce the contact resistance and provide mechanical strength, the seal ring structure 2040 is coupled to the first thermal bump feature 300-1 by way of a first thermal contact via 410. In some instances, the first thermal contact via 410 is circular in a top view and has a first via diameter V1. In some implementations, the first via diameter V1 is between about 50% and about 90% of the first diameter D1. Because the first via diameter V1 is too much greater than a thickness of the redistribution line in the interposer 204, the first via diameter V1 has a multi-layer construction. In the embodiment depicted in FIG. 7, a metal island 408 is formed in the insulation layer 2044 by depositing a seed layer and depositing a metal fill over the seed layer using electroplating or electroless plating. In some embodiments, the seed layer includes copper (Cu), titanium (Ti), or alloy thereof. A trench is formed along the sidewall of the first thermal contact via. Then the redistribution line 2042 and a metal outer layer 406. In some embodiments represented in FIG. 7, the metal island 408 is embedded in the metal outer layer 406. In other words, the metal outer layer 406 surrounds the metal island 408. In some implementations, the first thermal contact via 410 partially extends into the first copper pillar 302.

FIG. 8 illustrates a schematic cross-sectional view of a second thermal bump feature 300-2. The second thermal bump feature 300-2 includes a second copper pillar 304 and a second solder cap 314 over the second copper pillar 304. In some embodiments, the second copper pillar 304 may include copper (Cu), nickel (Ni), or cobalt (Co) and the second solder cap 314 may include tin (Sn), silver (Ag). In some embodiments, the second thermal bump feature 300-2 is substantially circular in a top view and has a second diameter D2. In some instances, the second diameter D2 may be between about 30% and about 100% of the first diameter D1. In one embodiment, the second diameter D2 is smaller than the first diameter D1. Instead of interfacing the first thermal contact via 410 that has a multi-layer construction, the seal ring structure 2040 interfaces the second thermal bump feature 300-2 by way of a plurality of second thermal contact vias 412. While FIG. 8 illustrates only two second thermal contact vias 412, it should be understood that additional second thermal contact vias 412 are fully envisioned. Although not explicitly shown in FIG. 8, a number of the second thermal contact vias 412 interfacing the second thermal bump feature 300-2 may be between 2 and 20. As described above, formation of the first thermal contact via 410 requires formation of a metal island 408 before forming the rest of the redistribution line and the metal outer layer 406. Because the second thermal bump feature 300-1 does not perform any circuit or power transmission functions, the plurality of second thermal contact via 412 are implemented here to reduce the process complexity. This is so because it does not matter if the second thermal contact via 412 provide a different contact resistance than the first thermal contact via 410. Additionally, the multiplicity of the second thermal contact vias 412 allows adjustment of the number of second thermal contact vias 412 to accommodate the second thermal bump feature 300-2 of different dimensions. For example, when the second diameter D2 is about 100% of the first diameter D1, the number of the second thermal contact vias 412 that interface the second thermal bump feature 300-2 may be between 15 and 20. When the second diameter D2 is about 30% of the first diameter D1, the number of the second thermal contact vias 412 that interface the second thermal bump feature 300-2 is between 2 and 3. In some instances, each of the second thermal contact vias 412 is circular in a top view and has a second via diameter V2. In some implementations, the second via diameter V2 is between about 10% and about 20% of the second diameter D2.

FIG. 9 illustrates a schematic cross-sectional view of a third thermal bump feature 300-3. The third thermal bump feature 300-3 includes a third copper pillar 306 and a third solder cap 316 over the third copper pillar 306. In some embodiments, the third copper pillar 306 may include copper (Cu), nickel (Ni), or cobalt (Co) and the third solder cap 316 may include tin (Sn), silver (Ag). In some embodiments, the third thermal bump feature 300-3 is substantially circular in a top view and has a third diameter D3. In some instances, the third diameter D3 may be between about 10% and about 30% of the first diameter D1. Due to the smaller third diameter D3, the seal ring structure 2040 is coupled to the third thermal bump feature 300-3 by way of a single third thermal contact via 414. In some instances, the third thermal contact via 414 is circular in a top view and has a third via diameter V3. In some implementations, the third via diameter V3 is between about 25% and about 80% of the third diameter D3.

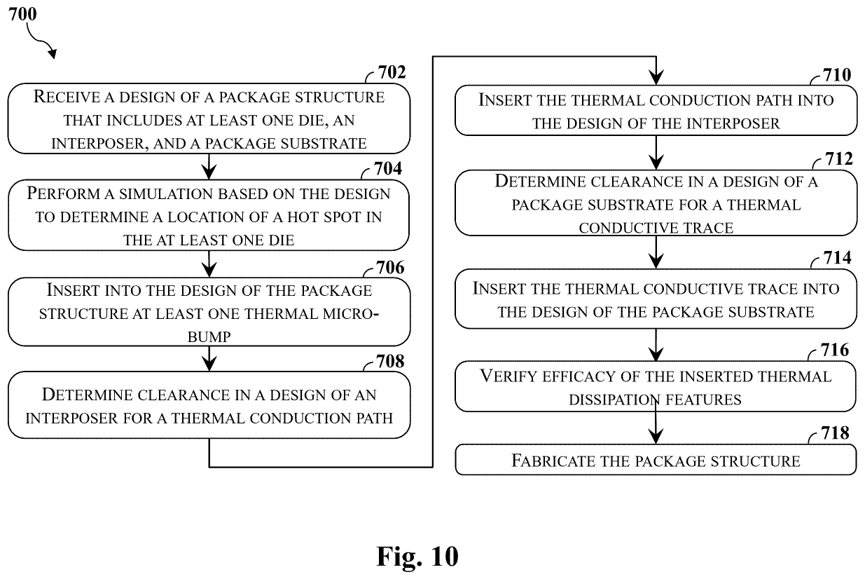

FIG. 10 illustrates a flowchart of a method 700 for implementing thermal dissipation structures in a package structure similar to the package structure 200 shown in FIGS. 1 and 2. Method 700 is merely an example and is not intended to limit the present disclosure to what is explicitly illustrated in method 700. Additional steps can be provided before, during and after method 700, and some steps described can be replaced, eliminated, or moved around for additional embodiments of the method. Not all steps are described herein in detail for reasons of simplicity.

Referring to FIG. 10, method 700 includes a block 702 a design of a package structure is received. Similar to the package structure 200 shown in FIGS. 1-6, the package structure according to the design includes at least one die, an interposer, and package substrate. For that reason, the design of the package structure at block 702 naturally includes a design of the at least one die, a design of the interposer, and a design of the package substrate. The at least one die is bonded to the interposer by way of micro bumps and the interposer is bonded tor the package substrate by way of C4 bumps. At block 702, the package structure according to the design does not include any heat dissipation features such as the thermal micro bump 222, the redistribution line 2048, and the thermal bump feature 300. The at least one includes a plurality of transistors, an interconnect structure, and a redistribution layer.

Referring to FIG. 10, method 700 includes a block 704 where a simulation based on the design of the package structure is performed to determine a location of a hot spot in the at least one die. At block 704, the design of the package structure is loaded into a simulation platform, such as a computer aided design (CAD) tool. In some instances, the design of the package structure may be converted into a different format in order for the CAD tool to simulation a standby operation and a peak operation of the package structure. The simulation(s) performed at block 704 help construct a heat map for the at least one die. When the package structure includes more than one die, like the package structure 200 shown in FIG. 1-6, the simulation(s) may generate a heat map for each of the dies. With help the CAD tool, the heat map for each of the die is filtered based on certain threshold criteria to generate a hot spot map. Example threshold criteria may include a pre-determined peak temperature and a pre-determined average operation temperature. It should be understood that the simulation(s) at block 704 may indicate more than one hot spot for some of the dies and zero hot spot for some of the dies.

Referring to FIG. 10, method 700 includes a block 706 where at least one thermal micro bump is inserted into the design of the package structure. As described above, a thermal micro bump is electrically insulated from any of the transistors in a die and does not perform any circuit function. That is, the design of the package structure is fully operational without the thermal micro bump to be inserted at block 706. At block 706, at least one thermal micro bump is inserted to be coupled to a redistribution line in the redistribution layer of the at least one die. To achieve efficient thermal dissipation, the thermal micro bump is inserted to be overlapping or adjacent a vertical projection area of the hot spot identified at block 704. It should be understood that more than one thermal micro bump may be inserted depending on the characteristic of the hot spot. For example, when a thermal micro bump cannot be inserted directly below a hot spot, more than one thermal micro bump may be inserted to compensate for this added distance. For another example, when the simulation at block 704 indicate unusually high temperature for a hot spot, more than one thermal micro bump may be inserted to prevent potential damages to the die. Block 706 also checks to ensure than none of the inserted thermal micro bump lands on a function feature in the interposer.

Referring to FIG. 10, method 700 includes a block 708 where clearance for insertion of a thermal conduction path in the design of the interposer is determined. For purposes of the present disclosure, the design of the interposer includes a seal ring structure similar to the seal ring structure 2040 shown in FIGS. 1-6. The thermal conduction path here includes a thermal redistribution line that electrically couple the micro thermal bumps inserted at block 706 to the seal ring structure in the interposer and a thermal bump feature coupled to the seal ring structure. Block 708 may result in different determinations. For example, block 708 may determine that the landing area of the thermal micro bump is surrounded by functional redistribution features. In that case, block 708 may check whether there is room for the thermal redistribution line in a different redistribution layer. When block 708 determines that there is no room for insertion of a thermal redistribution line, a thermal redistribution line will not be inserted and the thermal micro bump inserted at block 706 may simply land on an insulation layer of the interposer. For another example, block 708 determines whether there is room to insert a first thermal bump feature 300-1 (shown in FIG. 7), a second thermal bump feature 300-2 (shown in FIG. 8), or a third thermal bump feature 300-3 (shown in FIG. 9). When there is no room for the first thermal bump feature or the second thermal bump feature, block 708 may determine that the third thermal bump feature be inserted. Additionally, block 708 may determine whether there is room to insert a thermal via ring, similar to the thermal via ring 404 shown in FIGS. 5 and 6. As described above, a thermal via ring is an extension of the seal ring structure. Implementation of a thermal via ring is beneficial for heat dissipation provided there is room for its insertion.

Referring to FIG. 10, method 700 includes a block 710 where the thermal conduction path is inserted into the design of the interposer. When block 708 determines that there is enough room for insertion a part of or the entirety of the thermal conduction path, block 710 inserts the thermal conduction path into the design of the interposer.

Referring to FIG. 10, method 700 includes a block 712 where clearance for insertion of a thermal conductive trace in the design of the package substrate is determined. The thermal bump feature lands on the thermal conductive trace, when inserted, to further conduct heat downward and away from the die. An example of the thermal conductive trace is the thermal conductive trace 2022 shown in FIGS. 3-6. The thermal conductive trace allows heat from the thermal bump feature to dissipate into further conductive feature in the package substrate, such as other conductive traces and the solder bumps under the package substrate. For example, block 712 may determine that the landing area of the thermal bump is surrounded by functional conductive traces. In that case, block 712 may check whether there is room for the thermal conductive trace in a different redistribution layer. When block 712 determines that there is no room for insertion of a thermal conductive trace, a thermal conductive trace will not be inserted at block 714 and the thermal bump feature inserted at block 710 may simply land on an insulation layer of the package substrate.

Referring to FIG. 10, method 700 includes a block 714 where the thermal conductive trace is inserted into the design of the package substrate. When block 712 determines that there is enough room for insertion the thermal conductive trace, block 714 inserts the thermal conductive trace into the design of the package substrate.

Referring to FIG. 10, method 700 includes a block 716 where another simulation or another round of simulations are performed to verify the efficacy of the inserted thermal dissipation features. At block 716, the modified design of the package structure, which includes the inserted thermal dissipation features, is loaded into a simulation platform, such as a CAD tool. In some instances, the modified design of the package structure may be converted into a different format in order for the CAD tool to simulation a standby operation and a peak operation of the package structure. The simulation(s) performed at block 716 verify efficacy of the inserted thermal dissipation features, such as the thermal micro bumps, the thermal conduction path, and the thermal conductive trace. If the inserted thermal dissipation features indeed help lower temperatures at hot spots, method 700 proceeds to block 718 where the package structure is fabricated. If the inserted thermal dissipation features do not improve the heat distribution or improve to an insufficient extent, the thermal dissipation features may not be implemented, especially when their implementation increases manufacturing cost.

Referring to FIG. 10, method 700 includes a block 718 where the package substrate is fabricated. At block 718, provided that the thermal dissipation features do cool down the hot spots, the last one die, the interposer, and the package substrate are fabricated separately based on the modified design and are then bonded together.

The present disclosure provides many embodiments. In one aspect, the present disclosure provides a semiconductor package structure. The semiconductor package structure includes a substrate, an interposer bonded to the substrate by way of a plurality of first type solder features and including a redistribution structure and a seal ring structure extending around the redistribution structure, and an integrated circuit (IC) die bonded to the interposer by way of a plurality of second type solder features. At least one of the plurality of second type solder features is electrically coupled to the seal ring structure.

In some embodiments, within the interposer, the seal ring structure is electrically insulated from the redistribution structure. In some embodiments, the IC die includes a plurality of transistors and the at least one of the plurality of second type solder features electrically coupled to the seal ring structure is insulated from the plurality of transistors in the IC die. In some embodiments, the plurality of transistors in the IC die includes multi-gate transistors. In some embodiments, the seal ring structure is electrically coupled to at least one of the plurality of first type solder features by way of a contact via. In some embodiments, the seal ring structure is electrically coupled to at least one of the plurality of first type solder features by way of a via ring and the via ring extends continuously around a vertical projection area of the redistribution structure. In some implementations, the seal ring structure includes copper. In some embodiments, the substrate includes a plurality of conductive features and the seal ring structure is electrically insulated from the plurality of conductive features.

In another aspect, the present disclosure provides a semiconductor package structure. The semiconductor package structure includes a package substrate, an interposer bonded to the package substrate and including a redistribution structure and a seal ring structure extending around the redistribution structure, and an integrated circuit (IC) die bonded to the interposer by way of a plurality of first type solder features. At least one of the plurality of first type solder features is electrically coupled to the seal ring structure.

In some embodiments, the seal ring structure includes metal lines and metal vias and wherein the metal lines and metal vias extend through an entire thickness of the interposer. In some embodiments, the IC die includes a plurality of transistors and the at least one of the plurality of first type solder features is electrically insulated from the plurality of transistors. In some implementations, the interposer is bonded to the package structure by way of a plurality of second type solder features. In some instances, the seal ring structure is electrically coupled to at least one of the plurality of second type solder features by way of a contact via. In some instances, the seal ring structure is electrically coupled to the at least one of the plurality of second type solder features by way of a via ring and wherein the via ring extends continuously around a vertical projection area of the redistribution structure. In some embodiments, within the interposer, the seal ring structure is insulated from the redistribution structure.

In still another aspect, the present disclosure provides a semiconductor package structure. The semiconductor package structure includes a package substrate, an interposer bonded to the package substrate and including a redistribution structure, and a seal ring structure extending around the redistribution structure, and an integrated circuit (IC) die having a plurality of transistors and bonded to the interposer by way of a plurality of contact features. The plurality of contact features includes a first subset of contact features and a second subset of contact features. The first subset of contact features are electrically coupled to the plurality of transistors. The second subset of contact features are electrically isolated from the plurality of transistors. The second subset of contact features are electrically coupled to the seal ring structure.

In some embodiments, the plurality of transistors in the IC die includes multi-gate transistors. In some embodiments, the first subset of contact features is electrically coupled redistribution structure. In some implementations, the interposer is bonded to the package substrate by way of a plurality of solder features and the seal ring structure is bonded to the package substrate by way of at least one of the plurality of solder features. In some instances, the seal ring structure is electrically coupled to the at least one of the plurality of solder features by way of a plurality of contact vias.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a substrate;
an interposer bonded to the substrate by way of a plurality of first type solder features, the interposer comprising:
a redistribution structure, and
a seal ring structure extending around the redistribution structure; and
an integrated circuit (IC) die bonded to the interposer by way of a plurality of second type solder features,
wherein at least one of the plurality of second type solder features is electrically coupled to the seal ring structure.

2. The semiconductor package structure of claim 1, wherein, within the interposer, the seal ring structure is electrically insulated from the redistribution structure.

3. The semiconductor package structure of claim 1,
wherein the IC die comprises a plurality of transistors,
wherein the at least one of the plurality of second type solder features electrically coupled to the seal ring structure is insulated from the plurality of transistors in the IC die.

4. The semiconductor package structure of claim 3, wherein the plurality of transistors in the IC die comprises multi-gate transistors.

5. The semiconductor package structure of claim 1, wherein the seal ring structure is electrically coupled to at least one of the plurality of first type solder features by way of a contact via.

6. The semiconductor package structure of claim 1,
wherein the seal ring structure is electrically coupled to at least one of the plurality of first type solder features by way of a via ring,
wherein the via ring extends continuously around a vertical projection area of the redistribution structure.

7. The semiconductor package structure of claim 1, wherein the seal ring structure comprises copper.

8. The semiconductor package structure of claim 1,
wherein the substrate comprises a plurality of conductive features,
wherein the seal ring structure is electrically insulated from the plurality of conductive features.

9. A semiconductor package structure, comprising:
a package substrate;
an interposer bonded to the package substrate and comprising:
a redistribution structure, and
a seal ring structure extending around the redistribution structure; and
an integrated circuit (IC) die bonded to the interposer by way of a plurality of first type solder features,
wherein at least one of the plurality of first type solder features is electrically coupled to the seal ring structure.

10. The semiconductor package structure of claim 9,
wherein the seal ring structure comprises metal lines and metal vias,
wherein the metal lines and metal vias extend through an entire thickness of the interposer.

11. The semiconductor package structure of claim 9,
wherein the IC die comprises a plurality of transistors,
wherein the at least one of the plurality of first type solder features is electrically insulated from the plurality of transistors.

12. The semiconductor package structure of claim 11, wherein the interposer is bonded to the package structure by way of a plurality of second type solder features.

13. The semiconductor package structure of claim 12, wherein the seal ring structure is electrically coupled to at least one of the plurality of second type solder features by way of a contact via.

14. The semiconductor package structure of claim 12,
wherein the seal ring structure is electrically coupled to the at least one of the plurality of second type solder features by way of a via ring,
wherein the via ring extends continuously around a vertical projection area of the redistribution structure.

15. The semiconductor package structure of claim 9, wherein, within the interposer, the seal ring structure is insulated from the redistribution structure.

16. A semiconductor package structure, comprising:
a package substrate;
an interposer bonded to the package substrate and comprising:
a redistribution structure, and
a seal ring structure extending around the redistribution structure; and
an integrated circuit (IC) die comprising a plurality of transistors and bonded to the interposer by way of a plurality of contact features,
wherein the plurality of contact features comprises a first subset of contact features and a second subset of contact features,
wherein the first subset of contact features are electrically coupled to the plurality of transistors,
wherein the second subset of contact features are electrically isolated from the plurality of transistors,
wherein the second subset of contact features are electrically coupled to the seal ring structure.

17. The semiconductor package structure of claim 16, wherein the plurality of transistors in the IC die comprises multi-gate transistors.

18. The semiconductor package structure of claim 16, wherein the first subset of contact features is electrically coupled redistribution structure.

19. The semiconductor package structure of claim 16,
wherein the interposer is bonded to the package substrate by way of a plurality of solder features,
wherein the seal ring structure is bonded to the package substrate by way of at least one of the plurality of solder features.

20. The semiconductor package structure of claim 19, wherein the seal ring structure is electrically coupled to the at least one of the plurality of solder features by way of a plurality of contact vias.
